(19) United States
(12) Patent Application Publication
(10) Pub. No.: US 2021/0071314 A1
(43) Pub. Date: Mar. 11, 2021

(54) SEMICONDUCTOR CRYSTAL GROWTH APPARATUS

(71) Applicant: ZING SEMICONDUCTOR CORPORATION, Shanghai (CN)

(72) Inventors: Weimin Shen, Shanghai (CN); Gang Wang, Shanghai (CN)

(21) Appl. No.: 17/016,446

(22) Filed: Sep. 10, 2020

(30) Foreign Application Priority Data
Sep. 11, 2019 (CN) 201910859971.4

(51) Int. Cl. C30B 15/14; C30B 15/10; C30B 29/06

(52) U.S. Cl. CPC C30B 15/14; C30B 29/06; C30B 15/10

(57) ABSTRACT

The present invention provides a crystal growth apparatus, including: a crucible configured to contain a melt for crystal growth; a heater disposed around the crucible and configured to heat the crucible; a heater deflector configured to surrounded the top and sides of the heater; an air vent, located on the heater deflector above the heater to let the air flow between the top space of the crystal growth apparatus and the surrounding space of the heater. According to the crystal growth device provided by the present invention, the air vent is provided on the heater deflector above the heater to connect the top space of the crystal growth device and the surrounding space of the heater, so that the heater is always in the atmosphere of the protective gas, the erosion of the heater surface by SiO vapor is avoided, the service life of the heater is extended, and the stability of the crystal growth quality is improved.

### CROSS-REFERENCE TO RELATED APPLICATIONS

This application claims priority to P.R.C. Patent Application No. 201910859971.4 titled “a semiconductor crystal growth apparatus” filed on Sep. 11, 2019, with the State Intellectual Property Office of the People's Republic of China (SIPO).

### TECHNICAL FIELD

The present invention relates to the field of crystal growth technology, and in particular, to a crystal growth device.

### BACKGROUND

With the rapid development of the integrated circuit (IC) industry, component manufacturers have put forward stricter requirements for IC grade silicon single crystal materials, and large diameter single crystal silicon is a necessary substrate material for the preparation of components. The Czochralski (CZ) method is one of the most important methods for growing single crystals from the melt in the prior art. The specific method is to put the raw materials constituting the crystal in a crucible and heat it to melt, and then put the seed crystal on the surface of the melt to pull up the melt, under controlled conditions, continuously rearranges the atoms and molecules at the interface between the seed crystal and the melt, and gradually solidifies as the temperature drops to grow crystals.

The crystal growth device is provided with a heater deflector to surround the top and sides of the heater to prevent erosion of the heater surface by SiO vapor. However, when SiO vapor diffuses around the heater, since there is almost no gas flow around the heater, erosion of the heater surface by SiO vapor may still occur.

### SUMMARY

A series of simplified forms of concepts are introduced in the Summary of the Invention section, which will be described in further detail in the Detailed Description section. The summary of the invention is not intended to limit the key features and essential technical features of the claimed invention, and is not intended to limit the scope of protection of the claimed embodiments.

An objective of the present invention is to provide a semiconductor crystal growth apparatus, the semiconductor crystal growth apparatus comprises:
crucible, configured to contain melt for crystal growth;
a heater arranged around the crucible and configured to heat the crucible;
a heater deflector configured to surround the top and sides of the heater;
at least one air vent, located on the heater deflector above the heater to let the air flow between the top space of the crystal growth apparatus and the surrounding space of the heater.

In accordance with some embodiments, the semiconductor crystal growth apparatus further comprises:
an exhaust device, located at the bottom of the crystal growth apparatus.

In accordance with some embodiments, the number of the air vent ranges from 4 to 64.

In accordance with some embodiments, the top space of the crystal growth apparatus is filled with a protective gas, and the protective gas comprises argon.

In accordance with some embodiments, the protective gas passing through the air vent is about 10% to 20% of the total gas flowed into the crystal growth apparatus.

In accordance with some embodiments, the heater deflector comprises:
a deflector sleeve, disposed between the heater and the crucible;
an auxiliary structure, connected with the deflector sleeve.

In accordance with some embodiments, the semiconductor crystal growth apparatus further comprises a furnace body and a heat insulation structure located on the inner wall of the furnace body, the auxiliary structure covers the heat insulation structure, and the air vent runs through the heat insulation structure above the heater.

In accordance with some embodiments, the thickness of the deflector sleeve is in the range of 2-20 mm.

In accordance with some embodiments, a distance between an inner surface of the heater deflector and a surface of the heater is greater than 5 mm.

In accordance with some embodiments, wherein the crucible comprises a graphite crucible, the melt comprises a silicon melt, and the heater comprises a graphite heater.

According to the crystal growth apparatus provided by the present invention, the air vent is provided on the heater deflector above the heater to connect the top space of the crystal growth apparatus and the surrounding space of the heater, so that the heater is always in the atmosphere of protective gas, the erosion of the heater surface by SiO vapor is avoided, the service life of the heater is prolonged, and the stability of the crystal growth quality is improved.

### BRIEF DESCRIPTION OF THE DRAWINGS

Exemplary embodiments will be more readily understood from the following detailed description when read in conjunction with the appended drawings, in which:

FIG. 1 is a schematic diagram of a prior art crystal growth apparatus;

FIG. 2 is a schematic diagram of a crystal growth apparatus according to an exemplary embodiment of the present invention.

### DETAILED DESCRIPTION

The embodiments of the present invention are described below by way of specific examples, and those skilled in the art can readily understand other advantages and effects of the present invention from the disclosure of the present disclosure. The present invention may be embodied or applied in various other specific embodiments, and various modifications and changes can be made without departing from the spirit and scope of the invention.

In the following description, while the invention will be described in conjunction with various embodiments, it will be understood that these various embodiments are not intended to limit the invention. On the contrary, the invention is intended to cover alternatives, modifications and equivalents, which may be comprised within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details or with equivalents thereof. In other instances, well known methods, procedures, components, and circuits have not been described in detail as not to unnecessarily obscure aspects of the invention.

To understand the invention thoroughly, the following descriptions will provide detail steps to explain a method for crystal growth control of a shouldering process according to the invention. It is apparent that the practice of the invention is not limited to the specific details familiar to those skilled in the semiconductor arts. The preferred embodiment is described as follows. However, the invention has further embodiments beyond the detailed description.

The terminology used herein is for the purpose of describing particular embodiments only and is not intended to be limiting of example embodiments. As used herein, the singular forms “a,” “an” and “the” are intended to comprise the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

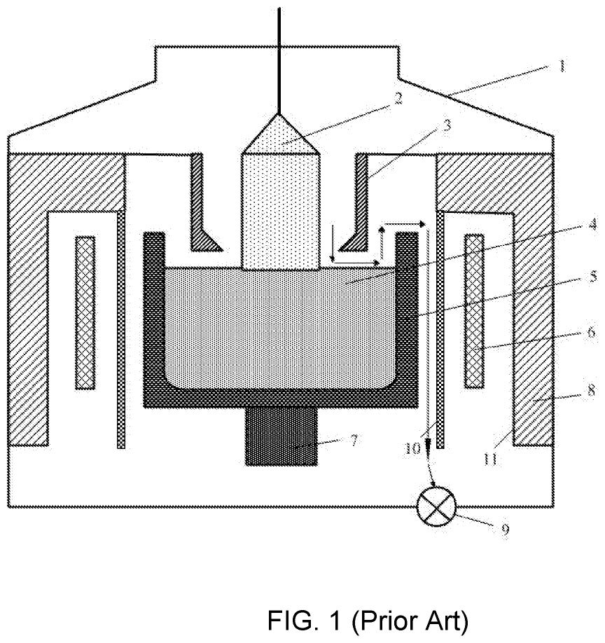

In the crystal growth apparatus shown in FIG. 1, during the crystal growth process of the CZ method, a large amount of oxygen atoms dissolve into the silicon melt due to high-temperature dissolution and diffusion of the inner wall of the quartz crucible in contact with the silicon melt. Most of the oxygen freely escapes from the surface of the silicon melt into argon gas in the form of SiO vapor. The SiO vapor reacts with graphite when passing through the high-temperature graphite surface of the heater 6 as the following formula:

SiO (gas)+2C (Solid)=CO (gas)+SiC (Solid) (Formula 1)

In addition, due to the presence of the plate-shaped fixing structure, most of the SiO vapor is prevented from diffusing into the upper part of the furnace body 1. Further, since the vacuum pump 9 is provided at the bottom of the furnace body 1, the SiO vapor is moving downward to the furnace body 1. Because of such movement, a large amount of SiO vapor passes through the heater 6 and reacts with the high-temperature graphite surface.

As the above reaction occurs, CO gas and argon gas are pumped out from the furnace body through the vacuum pump 9, SiC is deposited on the surface of the graphite piece, the graphite element in the crystal growth device is continuously eroded by the reaction, especially the high temperature graphite of the heater 6 surface. After a certain period of time or number of uses, the thickness and width of the graphite on the surface of the heater 6 will decrease, and the resistance of the heater 6 will gradually increase; at the same time, the heating range and heating effect of the heater 6 will also change, resulting the quality of crystal growth is unstable.

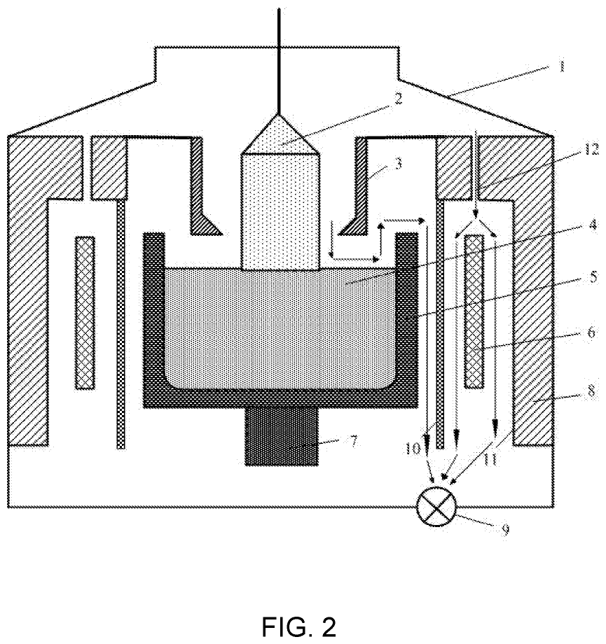

In view of the above problems, the present invention provides a crystal growth device, as shown in FIG. 2, comprising:
crucible 5, configured to contain melt 4 for crystal growth;
a heater 6 is provided around the crucible 5 and is configured to heat the crucible 5;
a heater deflector configured to surround the top and sides of the heater; and
a plurality of air vents 12 are provided on the heater deflector above the heater 6 to connect the top space of the crystal growth device and the surrounding space of the heater 6.

A crystal growth apparatus as shown in FIG. 2 comprises a furnace body 1, the furnace body 1 comprises a crucible 5, a heater 6 is provided on the periphery of the crucible 5, and a melt 4 is provided in the crucible 5, above the melt 4 is a crystal 2, and above the crucible 5 there is a reflective screen 3 surrounding the crystal 2. As an example, the melt 4 in the crucible 5 is a silicon melt, and the grown crystal 2 is a single crystal silicon ingot.

In one embodiment, the furnace body 1 is a stainless steel cavity, and the furnace body 1 is vacuum or filled with protective gas. As an example, the protective gas is argon, whose purity is more than 97%, the pressure is 5 mbar-100 mbar, and the gas flow rate is 70 slm-200 slm.

In one embodiment, the crucible 5 is made of a material resistant to high temperature and corrosion, and the crucible 5 contains a melt for crystal growth. In one embodiment, the crucible 5 includes a quartz crucible and/or a graphite crucible, and the crucible 5 contains a silicon material, such as polycrystalline silicon. The silicon material is heated in the crucible 5 into a silicon melt for growing a single crystal silicon ingot. Specifically, the seed crystal is immersed in the silicon melt, and the seed crystal is driven to rotate through the seed crystal shaft and slowly pulled up to make the silicon atoms grown along the seed crystal into a single crystal silicon ingot. The seed crystal is formed by cutting or drilling a silicon single crystal with a certain crystal orientation. Common crystal orientations are <100>, <111>, <110>, etc. The seed crystal is generally a cylinder shape.

In one embodiment, a heater 6 is provided on the periphery of the crucible 5, and the heater 6 is a graphite heater, which may be provided on the side of the crucible 5, and configured to heat the crucible 5. Further, the heater 6 comprises one or more heaters arranged around the crucible 5 so that the thermal field of the crucible 5 is evenly distributed.

In one embodiment, the furnace body 1 is further provided with a reflective screen 3, which is located above the crucible 5 and is located outside the crystal 2 around the crystal 2 to avoid the heat of the melt 4 being transferred in the form of heat radiation, or the like into the furnace body 1, causing heat loss.

Besides, the crystal growth apparatus further comprises a crucible lifting mechanism 7 configured to support and rotate the crucible shaft to achieve the lifting and lowering of the crucible 5.

Besides, the crystal growth device further comprises a heat insulation structure 8, which is disposed on the inner wall of the furnace body 1 to prevent heat loss and achieve the thermal insulation of the furnace body 1. The heat insulation structure 8 is located above and outside sidewall of the heater 6.

In one embodiment, the crystal growth device further comprises an exhaust device, which is provided at the bottom of the furnace body and configured to extract the gas in the furnace body 1. In one embodiment, the exhaust device comprises a vacuum pump 9 that exhausts the gas in the furnace body 1 from the lower side of the furnace body 1.

The vacuum pump 9 is disposed at the bottom of the furnace body 1 and the lower side exhaust is used. Compared with the vacuum pump 9 disposed at the upper portion of the furnace body 1 and using the upper exhaust gas, the upper exhaust gas causes a greater heat loss in the upper portion of the furnace body 1, and the uneven temperature in the circumferential direction leads to a decrease in the crystal growth yield, and the use of the lower exhaust gas has a small effect on the temperature of the area around the crystal growth, ensuring good growth of the crystal.

As shown in FIG. 2, the reflective screen 3 is connected to the heat insulation structure 8 through a fixing structure to fix the reflective screen 3 above the crucible 5. The fixing structure is usually a plate-like structure, therefore, the existence of the fixing structure can avoid the gas circulation above and below the fixing structure.

The present invention also comprises a heater deflector. As shown in FIG. 2, the heater deflector comprises:
a deflector sleeve 10, which is provided between the heater 6 and the crucible 5;
an auxiliary structure 11, the deflector sleeve 10 is connected to the auxiliary structure 11 to surround the top and sides of the heater 6.

Exemplarily, the thickness range of the deflector sleeve 10 is preferably set to 2 mm-20 mm. By controlling the thickness range of the deflector sleeve 10, the deflector sleeve 10 can achieve the effect of blocking SiO vapor without affecting the heat radiation of the heater 6 to the crucible 5.

Further, the distance between the inner surface of the heater deflector and the surface of the heater is greater than 5 mm to form a surrounding space around the heater 6.

By forming a cover that surrounds the top and sides of the heater 6, the heater 6 can be separated from the air flow channel, as shown in FIG. 2. The air flows in the bottom portion of the furnace body 1 and pumped out. Under the isolation effect of the deflector sleeve 10, the SiO vapor does not pass through the heater 6, that prevents the SiO vapor from reacting with the high-temperature graphite surface of the heater 6.

However, when SiO vapor diffuses into the space around the heater 6, since there is almost no gas flow around the heater 6, erosion of the heater surface by the SiO vapor may still occur. Therefore, the present invention further comprises a plurality of air vents 12, which are provided on the heater deflector above the heater 6 to connect the top space of the crystal growth device and the surrounding space of the heater 6.

Exemplarily, the upper and outer sides of the heater 6 are both heat-insulating structures 8, configured to prevent heat loss to achieve heat preservation of the furnace body 1, and the auxiliary structure 11 covers the heat-insulating structure 8 to communicate with the deflector sleeve 10 is connected to form a cover surrounding the top and sides of the heater 6.

In one embodiment, the air vents 12 run through the heat insulation structure 8 above the heater.

By providing air vents 12 above the heater 6, under the action of the vacuum pump 9 at the bottom of the furnace body 1, the protective gas (for example, argon) in the top space of the furnace body 1 enters the enclosure through the air vents 12, then, it pumped out from the bottom of the furnace body 1 to form an airflow channel through the surrounding space of the heater 6. Therefore, the SiO vapor diffused into the housing is pumped out, and the heater 6 is always in the atmosphere of the protective gas.

Exemplarily, the number of the air vents 12 may be selected as needed to control the flow rate and/or flow rate of the gas flowing through the space around the heater 6. Exemplarily, the cross-sectional area of the air vents 12 may be tuned as needed to control the flow rate and/or flow rate of the gas flowing through the space around the heater 6. In addition, the flow rate and/or flow rate of the gas flowing through the space around the heater 6 can also be controlled by tuning the total flow rate of the protective gas entering the furnace body or the parameters of the vacuum pump 9.

In one embodiment, the flow rate of the protective gas passing through the air vents 12 accounts for 10% to 20% of the total flow rate of the protective gas flown into the furnace body 1, and the number range of the air vents 12 is ranging from 4 to 64.

According to the crystal growth apparatus provided by the present invention, the air vents are provided on the heater deflector above the heater to connect the top space of the crystal growth apparatus and the surrounding space of the heater, so that the heater is in the atmosphere of flowing protective gas, the erosion of the heater surface by SiO vapor is avoided, the service life of the heater is extended, and the stability of the crystal growth quality is improved.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A semiconductor crystal growth apparatus, comprising:
crucible, configured to contain melt for crystal growth;
a heater arranged around the crucible and configured to heat the crucible;
a heater deflector configured to surround the top and sides of the heater;
at least one air vent, located on the heater deflector above the heater to let the air flow between the top space of the crystal growth apparatus and the surrounding space of the heater.

2. The apparatus according to claim 1, further comprising:
an exhaust device, located at the bottom of the crystal growth apparatus.

3. The apparatus according to claim 1, wherein the number of the air vent ranges from 4 to 64.

4. The apparatus according to claim 1, wherein the top space of the crystal growth apparatus is filled with protective gas, and the protective gas comprises argon.

5. The apparatus according to claim 4, wherein the protective gas passing through the air vent is about 10% to 20% of the total gas flowed into the crystal growth apparatus.

6. The apparatus according to claim 1, wherein the heater deflector comprises:
a deflector sleeve, disposed between the heater and the crucible;
an auxiliary structure, connected with the deflector sleeve.

7. The apparatus according to claim 6, further comprising a furnace body and a heat insulation structure located on the inner wall of the furnace body, wherein the auxiliary structure covers the heat insulation structure, and the air vent runs s through the heat insulation structure above the heater.

8. The apparatus according to claim 6, wherein a thickness of the deflector sleeve is in the range of 2-20 mm.

9. The apparatus according to claim 1, wherein a distance between an inner surface of the heater deflector and a surface of the heater is greater than 5 mm.

10. The apparatus according to claim 1, wherein the crucible comprises a graphite crucible, the melt comprises a silicon melt, and the heater comprises a graphite heater.
